(19) United States
(12) Patent Application Publication
(10) Pub. No.: US 2026/0150514 A1
(43) Pub. Date: May 28, 2026

(54) DISPLAY PANEL AND METHOD FOR PREPARING THE SAME

(71) Applicants: Hefei Visionox Technology Co., Ltd., Hefei (CN); Visionox Technology Inc., Kunshan (CN)

(72) Inventors: Zhiwei ZHOU, Hefei (CN); Peng QIN, Kunshan (CN); Jinfang ZHANG, Hefei (CN); Lu ZHANG, Kunshan (CN); Yang YANG, Hefei (CN)

(73) Assignees: Hefei Visionox Technology Co., Ltd., Hefei (CN); Visionox Technology Inc., Kunshan (CN)

(21) Appl. No.: 19/372,223

(22) Filed: Oct. 28, 2025

(30) Foreign Application Priority Data
Oct. 30, 2024 (CN) 202411535734.X

(51) Int. Cl. H10K 59/122; H10K 59/12; H10K 59/35; H10K 59/80; H10K 71/00; H10K 71/20; H10K 71/60

(52) U.S. Cl. CPC H10K 59/122; H10K 59/1201; H10K 59/35; H10K 59/873; H10K 71/231; H10K 71/60; H10K 71/621

(57) ABSTRACT

The present application provides a display panel and a method for preparing the same. The display panel includes a substrate, an isolation structure, and a light-emitting device layer. A first film layer, a second film layer, and a third film layer are arranged to form the isolation structure, and an orthogonal projection of the first film layer arranged close to the substrate on the substrate is located within an orthogonal projection of the second film layer on the substrate. The extension distances corresponding to at least two light-emitting units are different, and some light-emitting units correspond to larger extension distances of the isolation structure. Since the periphery of the first electrode overlaps with the third film layer of the isolation structure, the first electrodes corresponding to light-emitting units with larger extension distances have larger overlap areas with the third film layer of the isolation structure.

### CROSS-REFERENCE TO RELATED APPLICATION

The application claims priority to Chinese Patent Application No. 202411535734.X, filed on Oct. 30, 2024, entitled “Display Panel, Display Device, and Method for Preparing Display Panel”, the entire contents of which are incorporated herein by reference.

### FIELD

The present application relates to the display field, and specifically relates to a display panel and a method for preparing the display panel.

### BACKGROUND

In Flat panel display devices based on Organic Light Emitting Diode (OLED) and Light Emitting Diode (LED) technologies have been widely used in various consumer electronic products such as mobile phones, televisions, laptops, desktop computers, etc., due to their advantages of high picture quality, power saving, thin body, and wide application range, becoming mainstream in display devices.

However, the performance of current OLED display products needs to be improved.

### SUMMARY

Embodiments of the present application provide a display panel and a display apparatus, which can improve display reliability.

Embodiments of the present application provide a display panel and a method for preparing the display panel, aiming to improve the performance of the display panel.

Some embodiments of the present application provide a display panel, including: a substrate; an isolation structure disposed on the substrate, and the isolation structure encircles a plurality of isolation openings, the isolation structure includes a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate; a light-emitting device layer disposed on the substrate, and the light-emitting device layer includes a plurality of light-emitting units, and at least a portion of the light-emitting unit is disposed in the isolation opening, and a distance between an orthogonal projection of an edge of the first film layer close to the light-emitting unit on the substrate and an orthogonal projection of an edge of the third film layer close to the same light-emitting unit on the substrate is an extension distance, and the extension distances corresponding to at least two light-emitting units are different.

Embodiments of the present application provide a display panel, including: a substrate; an isolation structure disposed on the substrate, and the isolation structure forms a plurality of isolation openings by enclosing, the isolation structure includes a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate; a light-emitting device layer disposed on the substrate, and the light-emitting device layer includes a plurality of light-emitting units, and at least a portion of the light-emitting unit is disposed in the isolation opening; the light-emitting unit includes a light-emitting portion and a first electrode; the first electrode is disposed on a side of the light-emitting portion away from the substrate, and the first electrode is electrically connected to the third film layer; and an area where the first electrode covers the third film layer is an overlap area, and the overlap areas corresponding to the first electrodes of at least two light-emitting units are different, a width of an overlapping portion between an orthogonal projection of the first electrode on the substrate and an orthogonal projection of the third film layer on the substrate is a first overlap width, and the first overlap widths corresponding to the first electrodes of at least two light-emitting units are different.

Embodiments of the present application provide a method for preparing a display panel, the method including: forming an isolation structure on a substrate, and the isolation structure forms a plurality of isolation openings by enclosing, the isolation structure includes a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate; forming at least a portion of film the layers, ex. one or some film layers of the plurality of film layers, of a light-emitting device layer on the substrate, and the light-emitting device layer includes a plurality of light-emitting units, a distance between an orthogonal projection of an edge of the first film layer close to the light-emitting unit on the substrate and an orthogonal projection of an edge of the third film layer close to the same light-emitting unit on the substrate is an extension distance, and the extension distances corresponding to at least two light-emitting units are different.

According to embodiments of the present application, the display panel includes a substrate, an isolation structure, and a light-emitting device layer. The first film layer, second film layer, and third film layer are arranged to form the isolation structure, and the first film layer arranged close to the substrate has an orthogonal projection on the substrate that is located within the orthogonal projection of the second film layer on the substrate. The area of the second film layer is larger than that of the first film layer, and the second film layer covers the surface of the first film layer close to the second film layer, causing the first film layer to be recessed relative to the second film layer in a direction away from the isolation opening.

When forming the light-emitting material layer of the light-emitting device layer, the light-emitting material layer produces a large height difference at the edge of the isolation structure, and since the first film layer is recessed relative to the second film layer, the light-emitting material layer is difficult to connect at the edge of the isolation structure, resulting in breakage. The breakage of the light-emitting material layer forms separated light-emitting portions, thereby reducing carrier crosstalk within the light-emitting material layer and improving the display effect of the display panel. Moreover, the preparation of light-emitting units does not require precise masks, reducing the development and use of precise masks and lowering production costs. The extension distances corresponding to at least two light-emitting units are different, with some light-emitting units corresponding to larger extension distances of the isolation structure. Since the periphery of the first electrode overlaps with the third film layer of the isolation structure, the first electrodes corresponding to light-emitting units with larger extension distances have larger overlap areas with the third film layer of the isolation structure, thereby reducing the overlap impedance between these first electrodes and the isolation structure, improving the light-emitting effect of the light-emitting units and the performance of the display panel.

### BRIEF DESCRIPTION OF THE DRAWINGS

FIG. 1 is a partial cross-sectional view of a display panel according to an embodiment of the present application;

FIG. 2 is a partial cross-sectional view of a display panel according to another embodiment;

FIG. 3 is a partial cross-sectional view of a display panel according to yet another embodiment;

FIG. 4 is a partial cross-sectional view of a display panel according to still another embodiment;

FIG. 5 is a partial cross-sectional view of a display panel according to another embodiment;

FIG. 6 is a partial cross-sectional view of a display panel according to another embodiment;

FIG. 7 is a partial cross-sectional view of a display panel according to another embodiment;

FIG. 8 is a partial cross-sectional view of a display panel according to another embodiment;

FIG. 9 is a partial cross-sectional view of a display panel according to another embodiment;

FIG. 10 is a partial cross-sectional view of a display panel according to another embodiment;

FIG. 11 is a partial cross-sectional view of a display panel according to another embodiment;

FIG. 12 is a flow diagram of a method for preparing a display panel according to an embodiment of the present application; and

FIGS. 13 to 22 are process diagrams for preparing a display panel according to an embodiment of the present application.

### DETAILED DESCRIPTION

Embodiments of the present application are described in further detail below with reference to the drawings and embodiments. The detailed description and drawings of the following embodiments are used to illustrate the principles of the present application instead of limiting the scope of the present application. That is, the present application is not limited to the described embodiments.

In a display panel, In this document, relational terms such as “first” and “second” are used solely to distinguish one entity or operation from another entity or operation, and do not necessarily require or imply any actual relationship or sequence between these entities or operations. Moreover, the terms “include,” “comprise,” or any other variants thereof are intended to cover non-exclusive inclusion, and a process, method, article, or apparatus that comprises a list of elements that do not include only those elements but may include other elements not expressly listed or inherent to such process, method, article, or apparatus. Without further limitation, the elements defined by the statement “including . . . ” do not exclude additional identical elements in the process, method, article, or apparatus that comprises the stated elements.

It should be understood that when describing the structure of components, when one layer or region is described as being “on” or “above” another layer or region, it may refer to being directly on the other layer or region, or there may be other layers or regions between them. Furthermore, if the component is inverted, the one layer or region will be “below” or “under” the other layer or region.

The embodiments of the present application provide a display panel, a display device, and a method for preparing a display panel. The following description will explain various embodiments of the display panel, display device, and method for preparing the display panel in conjunction with the drawings.

The embodiments of the present application provide a display panel, which can be an Organic Light Emitting Diode (OLED) display panel.

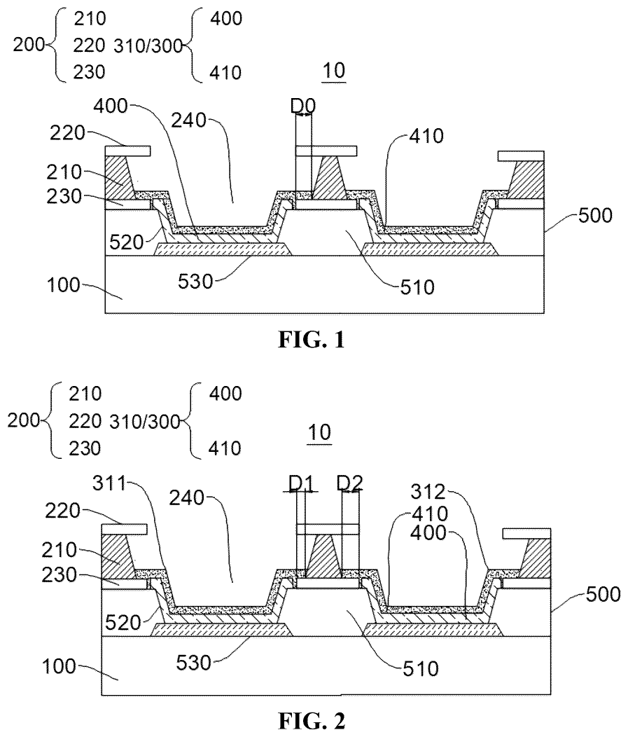

Please refer to FIG. 1, which is a partial cross-sectional view of a display panel according to an embodiment of the present application.

As shown in FIG. 1, the present embodiment provides a display panel 10, which includes: a substrate 100, an isolation structure 200, and a light-emitting device layer 300.

The isolation structure 200 is disposed on the substrate 100. One or a plurality of isolation openings 240 are encircled by the isolation structure 200. The isolation structure 200 includes a first film layer 210, a second film layer 220 disposed on a side of the first film layer 210 away from the substrate 100, and a third film layer 230 disposed on a side of the first film layer 210 facing the substrate 100. An orthogonal projection of the first film layer 210 on the substrate 100 is located within an orthogonal projection of the second film layer 220 on the substrate 100, and the orthogonal projection of the first film layer 210 on the substrate 100 is located within an orthogonal projection of the third film layer 230 on the substrate 100. The light-emitting device layer 300 is disposed on the substrate 100, and the light-emitting device layer 300 includes a plurality of light-emitting units 310, and at least a portion of the light-emitting unit 310 is disposed in the isolation opening 240. A distance between an orthogonal projection of an edge of the first film layer 210 close to the light-emitting unit 310 on the substrate 100 and an orthogonal projection of an edge of the third film layer 230 close to the same light-emitting unit 310 on the substrate 100 is an extension distance D0, and the extension distances D0 corresponding to at least two light-emitting units 310 are different.

The extension distance D0 corresponding to the light-emitting unit 310 refers to the extension distance D0 of the isolation structure 200 at the periphery of the isolation opening 240 where the light-emitting unit 310 is located, that is, the extension distance D0 formed by the first film layer 210 and the third film layer 230 on the side close to the light-emitting unit 310. The extension distance D0 may be a dimension by which the third film layer 230 protrudes beyond the first film layer 210 in a direction toward the isolation opening 240.

According to the embodiments of the present application, the display panel 10 includes a substrate 100, an isolation structure 200, and a light-emitting device layer 300. The first film layer 210, second film layer 220, and third film layer 230 are arranged to form the isolation structure 200, and the first film layer 210 arranged close to the substrate 100 has an orthogonal projection on the substrate 100 that is located within the orthogonal projection of the second film layer 220 on the substrate 100. The area of the second film layer 220 is larger than that of the first film layer 210, and the second film layer 220 covers the surface of the first film layer 210 close to the second film layer 220, causing the first film layer 210 to be recessed relative to the second film layer 220 in a direction away from the isolation opening 240. When forming the light-emitting material layer of the light-emitting device layer 300, the light-emitting material layer produces a large height difference at the edge of the isolation structure 200, and since the first film layer 210 is recessed relative to the second film layer 220, the light-emitting material layer is difficult to connect at the edge of the isolation structure 200, resulting in breakage. The breakage of the light-emitting material layer forms separated light-emitting portions 400, thereby reducing carrier crosstalk within the light-emitting material layer and improving the display effect of the display panel 10. Moreover, the preparation of light-emitting units 310 does not require precise masks, reducing the development and use of precise masks and reducing production costs. The extension distances D0 corresponding to at least two light-emitting units 310 are different, with some light-emitting units 310 corresponding to larger extension distances D0 of the isolation structure 200. Since the periphery of the first electrode 410 overlaps with the third film layer 230 of the isolation structure 200, the first electrodes 410 corresponding to light-emitting units 310 with larger extension distances D0 have larger overlap areas with the third film layer 230 of the isolation structure 200, thereby reducing the overlap impedance between these first electrodes 410 and the isolation structure 200, improving the light-emitting effect of the light-emitting units 310 and the performance of the display panel 10.

To obtain the recessed first film layer 210, during the etching process, the first film layer 210 has a faster etching rate compared to the second film layer 220 and third film layer 230, thereby forming the recessed first film layer 210. Due to the faster etching rate of the first film layer 210, more etching waste is produced which can easily enter other positions of the display panel 10, causing adverse effects. After setting up the third film layer 230, the first film layer 210 can better adhere to the third film layer 230, and the etching waste falls on the third film layer 230, making it easier to clean.

There are multiple ways to configure the substrate 100. For example, the substrate 100 can include a base substrate and an array substrate disposed on the base substrate. Or the substrate 100 can be just the base substrate. Or the substrate 100 can include a buffer layer and a supporting plate on the side away from the base substrate.

The composition, preparation, and other content of the isolation structure 200 are further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A for reference.

In some embodiments, the material of the third film layer 230 includes at least one of titanium nitride, titanium, and molybdenum nitride.

In these embodiments, materials such as titanium nitride, titanium, and molybdenum nitride have good wet etching resistance. When performing wet etching processes on the display panel 10, the surface of the third film layer 230 made of materials such as titanium nitride, titanium, and molybdenum nitride is difficult to oxidize. The third film layer 230 maintains good conductivity, thereby avoiding the problem of reduced display effect of the display panel 10 caused by the oxidation of the first film layer 210 surface when it overlaps with the first electrode 410, which would lead to reduced conductivity of the first film layer 210 and excessive overlap impedance with the first electrode 410. The material of the third film layer 230 can also be other wet etching-resistant materials that are difficult to oxidize, thus maintaining good conductivity and ensuring low overlap impedance between the third film layer 230 and the first electrode 410.

In some embodiments, the extension distances D0 corresponding to a plurality of light-emitting units 310 having the same light-emitting color are the same.

In these embodiments, the first electrodes 410 corresponding to light-emitting units 310 of the same light-emitting color have the same overlap area with the third film layer 230 of the isolation structure 200, thereby ensuring similar or identical overlap impedance between these first electrodes 410 and the third film layer 230. Light-emitting units 310 of the same color have similar or identical light-emitting effects, improving the display uniformity of the display panel 10. When the extension distances D0 corresponding to light-emitting units 310 of the same color are the same, it becomes easier to compare the extension distances D0 between light-emitting units 310 of different colors.

Please refer to FIG. 2, which is a partial cross-sectional view of a display panel according to another embodiment.

As shown in FIG. 2, in some embodiments, the light-emitting unit 310 includes a first light-emitting unit 311 and a second light-emitting unit 312, and the extension distance D0 corresponding to the first light-emitting unit 311 is a first distance D1, the extension distance D0 corresponding to the second light-emitting unit 312 is a second distance D2, and the first distance D1 is less than or equal to the second distance D2.

For example, the first light-emitting unit 311 and the second light-emitting unit 312 have different light-emitting colors.

The extension distance D0 corresponding to the first light-emitting unit 311 refers to the extension distance D0 of the isolation structure 200 at the periphery of the isolation opening 240 where the first light-emitting unit 311 is located, that is, the extension distance D0 formed by the first film layer 210 and the third film layer 230 on the side close to the first light-emitting unit 311. The extension distance D0 corresponding to the second light-emitting unit 312 refers to the extension distance D0 of the isolation structure 200 at the periphery of the isolation opening 240 where the second light-emitting unit 312 is located, that is, the extension distance D0 formed by the first film layer 210 and the third film layer 230 on the side close to the second light-emitting unit 312.

In these embodiments, the first distance D1 is less than or equal to the second distance D2. For example, the peripheries of the first electrodes 410 corresponding to the first light-emitting unit 311 and the second light-emitting unit 312 overlap with the third film layer 230 of the isolation structure 200. The isolation structure 200 corresponding to the second light-emitting unit 312 has a larger extension distance D0, making the overlap area between the first electrode 410 of the second light-emitting unit 312 and the third film layer 230 of the isolation structure 200 larger, thereby reducing the overlap impedance between this portion of the first electrode 410 and the isolation structure 200, improving the light-emitting effect of the second light-emitting unit 312.

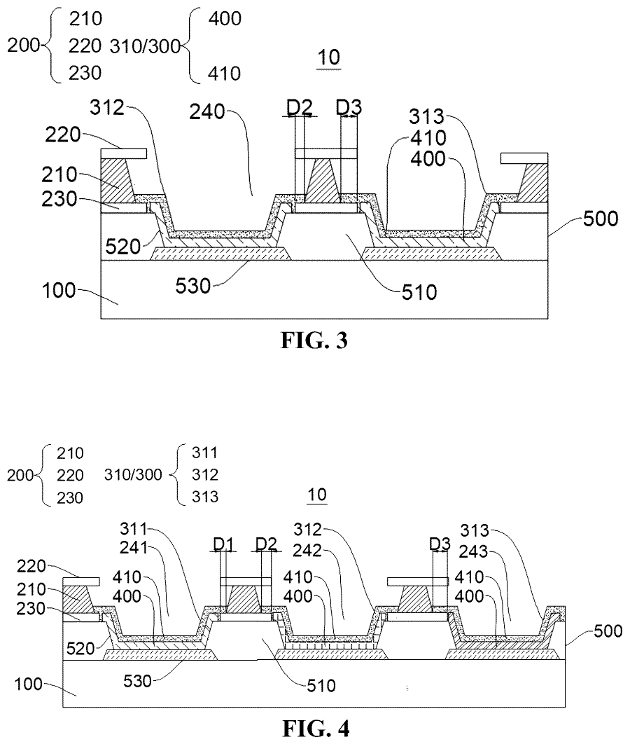

Please refer to FIG. 3, which is a partial cross-sectional view of a display panel according to yet another embodiment.

As shown in FIG. 3, in some embodiments, the light-emitting unit 310 further includes a third light-emitting unit 313, and the extension distance D0 corresponding to the third light-emitting unit 313 is a third distance D3, and the second distance D2 is less than or equal to the third distance D3.

The extension distance D0 corresponding to the third light-emitting unit 313 refers to the extension distance D0 of the isolation structure 200 at the periphery of the isolation opening 240 where the third light-emitting unit 313 is located, that is, the extension distance D0 formed by the first film layer 210 and the third film layer 230 on the side close to the third light-emitting unit 313.

In these embodiments, the second distance D2 is less than or equal to the third distance D3. For example, the peripheries of the first electrodes 410 corresponding to the second light-emitting unit 312 and the third light-emitting unit 313 overlap with the third film layer 230 of the isolation structure 200. The isolation structure 200 corresponding to the third light-emitting unit 313 has a larger extension distance D0, making the overlap area between the first electrode 410 of the third light-emitting unit 313 and the third film layer 230 of the isolation structure 200 larger, thereby reducing the overlap impedance between this portion of the first electrode 410 and the isolation structure 200, improving the light-emitting effect of the third light-emitting unit 313.

Please refer to FIG. 4, which is a partial cross-sectional view of a display panel according to still another embodiment.

As shown in FIG. 4, in one embodiment, the first distance D1 is less than or equal to the second distance D2, and the second distance D2 is less than or equal to the third distance D3. At least two of the first distance D1, the second distance D2, and the third distance D3 are different.

In an embodiment, the first light-emitting unit 311, second light-emitting unit 312, and third light-emitting unit 313 have different light-emitting colors. The light-emitting color of the first light-emitting unit 311 can be one of red, green, or blue. The light-emitting color of the second light-emitting unit 312 can be one of red, green, or blue. The light-emitting color of the third light-emitting unit 313 can be one of red, green, or blue. For example, the first light-emitting unit 311 can be a red light-emitting unit 310, the second light-emitting unit 312 can be a green light-emitting unit 310, and the third light-emitting unit 313 can be a blue light-emitting unit 310. In some embodiments, the light-emitting unit includes: a light-emitting portion 400 and a first electrode 410, and the first electrode 410 is disposed on a side of the light-emitting portion 400 away from the substrate 100, and the first electrode 410 (for example, cathode) is electrically connected to the isolation structure 200.

In these embodiments, the spaced-apart first electrodes 410 are electrically connected through the isolation structure 200 to form a complete electrode, ensuring normal light emission of the light-emitting units 310.

In an embodiment, the first distance D1, second distance D2, and third distance D3 are equal. When each isolation opening 240 is individually etched to form and prepare corresponding light-emitting units 310 and encapsulation portions, the final obtained isolation structure 200 can have equal first distance D1, second distance D2, and third distance D3. For example, firstly forming the isolation opening 240 corresponding to the first light-emitting unit 311 by etching, and preparing light-emitting portion 400, first electrode 410, and encapsulation portion of the first light-emitting unit, then forming the isolation opening 240 corresponding to the second light-emitting unit 312 by etching, and preparing the light-emitting portion 400, first electrode 410, and encapsulation portion of the second light-emitting unit 312, and finally forming the isolation opening 240 corresponding to the third light-emitting unit 313 by etching and preparing the light-emitting portion 400, first electrode 410, and encapsulation portion of the third light-emitting unit 313.

In some embodiments, in the same light-emitting unit 310, an orthogonal projection of the light-emitting portion 400 on the substrate 100 is located within an orthogonal projection of the first electrode 410 on the substrate 100. For example, in the same light-emitting unit 310, the area of an orthogonal projection of the light-emitting portion 400 on the substrate 100 is smaller than the area of an orthogonal projection of the first electrode 410 on the substrate 100.

In these embodiments, the orthogonal projection of the light-emitting portion 400 of the light-emitting unit 310 on the substrate 100 is located within the orthogonal projection of the first electrode 410 on the substrate 100, meaning the first electrode 410 covers the light-emitting portion 400 to serve as its electrode, ensuring normal light emission of the light-emitting portion 400 and improving the display effect of the display panel 10. The light-emitting portion 400 is spaced apart from the isolation structure 200, meaning the light-emitting units 310 are spaced apart from each other, reducing carrier crosstalk between light-emitting portions 400 and alleviating the color mixing problem of the light-emitting portions 400.

The first electrode 410 is electrically connected to the third film layer 230, providing a good overlap effect between the first electrode 410 and the third film layer 230. This can avoid the problem of reduced display effect of the display panel 10 caused by the oxidation of the first film layer 210 surface when it overlaps with the first electrode 410, which would lead to reduced conductivity of the first film layer 210 and excessive overlap impedance with the first electrode 410.

In some embodiments, an area where the first electrode 410 covers the third film layer 230 is an overlap area, and the overlap areas corresponding to the first electrodes 410 of at least two light-emitting units 310 are different.

In these embodiments, the periphery of the first electrode 410 overlaps with the third film layer 230 of the isolation structure 200. Some light-emitting units 310 have larger overlap areas between their corresponding first electrodes 410 and the third film layer 230 of the isolation structure 200, thereby reducing the overlap impedance between these first electrodes 410 and the isolation structure 200, improving the light-emitting effect of the light-emitting units 310 and the performance of the display panel 10.

In some embodiments, the overlap areas corresponding to a plurality of light-emitting units 310 having the same light-emitting color are the same.

The overlap area corresponding to a light-emitting unit 310 refers to the overlap area between the first electrode 410 of the light-emitting unit 310 and the third film layer 230.

In these embodiments, the first electrodes 410 corresponding to light-emitting units 310 of the same light-emitting color have the same overlap area with the third film layer 230 of the isolation structure 200, thereby ensuring similar or identical overlap impedance between these first electrodes 410 and the third film layer 230. Light-emitting units 310 of the same color have similar or identical light-emitting effects, improving the display uniformity of the display panel 10. When the overlap areas corresponding to light-emitting units 310 of the same color are the same, it becomes easier to compare the overlap areas between light-emitting units 310 of different colors.

In some embodiments, the light-emitting unit 310 includes a first light-emitting unit 311 and a second light-emitting unit 312, and the overlap area corresponding to the first light-emitting unit 311 is a first area, the overlap area corresponding to the second light-emitting unit 312 is a second area, and the first area is less than or equal to the second area.

The overlap area corresponding to the first light-emitting unit 311 refers to the overlap area between the first electrode 410 of the first light-emitting unit 311 and the third film layer 230, that is, the overlap area between the first electrode 410 of the first light-emitting unit 311 and the third film layer 230.

The overlap area corresponding to the second light-emitting unit 312 refers to the overlap area between the first electrode 410 of the second light-emitting unit 312 and the third film layer 230.

In these embodiments, the first area is less than or equal to the second area. For example, the peripheries of the first electrodes 410 corresponding to the first light-emitting unit 311 and the second light-emitting unit 312 overlap with the third film layer 230 of the isolation structure 200. The first electrode 410 corresponding to the second light-emitting unit 312 has a larger overlap area with the third film layer 230, thereby reducing the overlap impedance between this portion of the first electrode 410 and the isolation structure 200, improving the light-emitting effect of the second light-emitting unit 312.

In some embodiments, the light-emitting unit 310 further includes a third light-emitting unit 313, and the overlap area corresponding to the third light-emitting unit 313 is a third area, and the second area is less than or equal to the third area. At least two of the first area, second area, and third area are different.

The overlap area corresponding to the third light-emitting unit 313 refers to the overlap area between the first electrode 410 of the third light-emitting unit 313 and the third film layer 230.

In these embodiments, the second area is less than or equal to the third area. For example, the peripheries of the first electrodes 410 corresponding to the second light-emitting unit 312 and the third light-emitting unit 313 overlap with the third film layer 230 of the isolation structure 200. The first electrode 410 corresponding to the third light-emitting unit 313 has a larger overlap area with the third film layer 230, thereby reducing the overlap impedance between this portion of the first electrode 410 and the isolation structure 200, improving the light-emitting effect of the third light-emitting unit 313.

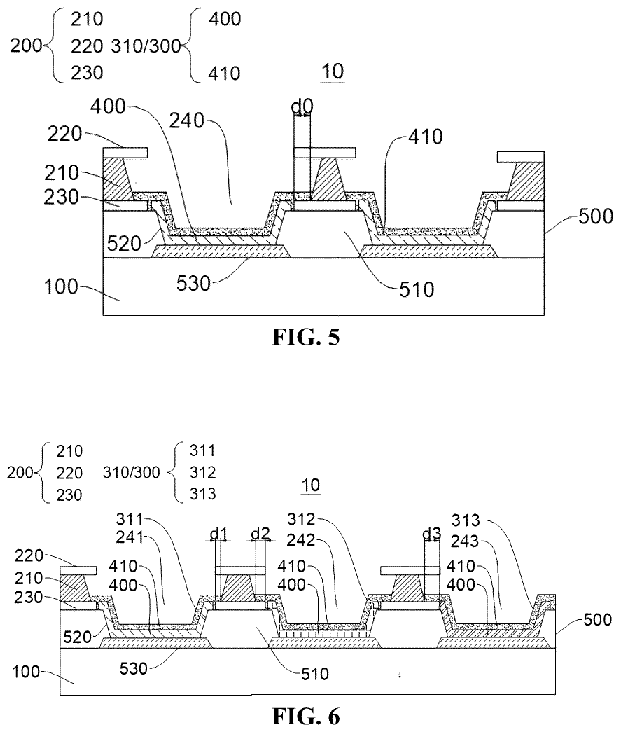

Please refer to FIG. 5, which is a partial cross-sectional view of a display panel according to another embodiment.

As shown in FIG. 5, in some embodiments, a width of an overlapping portion between an orthogonal projection of the first electrode 410 on the substrate 100 and an orthogonal projection of the third film layer 230 on the substrate 100 is a first overlap width d0, and the first overlap widths d0 corresponding to the first electrodes 410 of at least two light-emitting units 310 are different.

In these embodiments, the periphery of the first electrode 410 overlaps with the third film layer 230 of the isolation structure 200. The first electrodes 410 with larger first overlap widths d0 have larger overlap areas with the third film layer 230 of the isolation structure 200, thereby reducing the overlap impedance between these first electrodes 410 and the isolation structure 200, improving the light-emitting effect of the light-emitting units 310 and the performance of the display panel 10.

In some embodiments, the first overlap widths d0 corresponding to a plurality of light-emitting units 310 having the same light-emitting color are the same.

The first overlap width d0 corresponding to a light-emitting unit 310 refers to the overlap width d0 between the first electrode 410 of the light-emitting unit 310 and the third film layer 230.

In these embodiments, the first electrodes 410 corresponding to light-emitting units 310 of the same light-emitting color have the same first overlap width d0 with the third film layer 230 of the isolation structure 200, thereby ensuring similar or identical overlap impedance between these first electrodes 410 and the third film layer 230. Light-emitting units 310 of the same color have similar or identical light-emitting effects, improving the display uniformity of the display panel 10. When the overlap areas corresponding to light-emitting units 310 of the same color are the same, it becomes easier to compare the overlap areas between light-emitting units 310 of different colors.

Please refer to FIGS. 5 and 6, where FIG. 6 is a partial cross-sectional view of a display panel according to another embodiment.

As shown in FIG. 6, in some embodiments, the light-emitting unit includes a first light-emitting unit and a second light-emitting unit, and the first overlap width d0 corresponding to the first light-emitting unit is a first width d1, and the first overlap width d0 corresponding to the second light-emitting unit is a second width d2, and the first width d1 is less than or equal to the second width d2.

The first overlap width d0 corresponding to the first light-emitting unit 311 refers to the overlap width d0 between the first electrode 410 of the first light-emitting unit 311 and the third film layer 230.

The first overlap width d0 corresponding to the second light-emitting unit 312 refers to the overlap width d0 between the first electrode 410 of the second light-emitting unit 312 and the third film layer 230.

In these embodiments, the first width d1 is less than or equal to the second width d2. For example, the peripheries of the first electrodes 410 corresponding to the first light-emitting unit 311 and the second light-emitting unit 312 overlap with the third film layer 230 of the isolation structure 200. The first electrode 410 corresponding to the second light-emitting unit 312 has a larger first overlap width d0 with the third film layer 230, thereby reducing the overlap impedance between this portion of the first electrode 410 and the isolation structure 200, improving the light-emitting effect of the second light-emitting unit 312.

In some embodiments, the light-emitting unit 310 further includes a third light-emitting unit 313, and the first overlap width d0 corresponding to the third light-emitting unit 313 is a third width d3, and the second width d2 is less than or equal to the third width d3.

The first overlap width d0 corresponding to the third light-emitting unit 313 refers to the overlap width d0 between the first electrode 410 of the third light-emitting unit 313 and the third film layer 230.

In these embodiments, the second width d2 is less than or equal to the third width d3. For example, the peripheries of the first electrodes 410 corresponding to the second light-emitting unit 312 and the third light-emitting unit 313 overlap with the third film layer 230 of the isolation structure 200. The first electrode 410 corresponding to the third light-emitting unit 313 has a larger first overlap width d0 with the third film layer 230, thereby reducing the overlap impedance between this portion of the first electrode 410 and the isolation structure 200, improving the light-emitting effect of the third light-emitting unit 313.

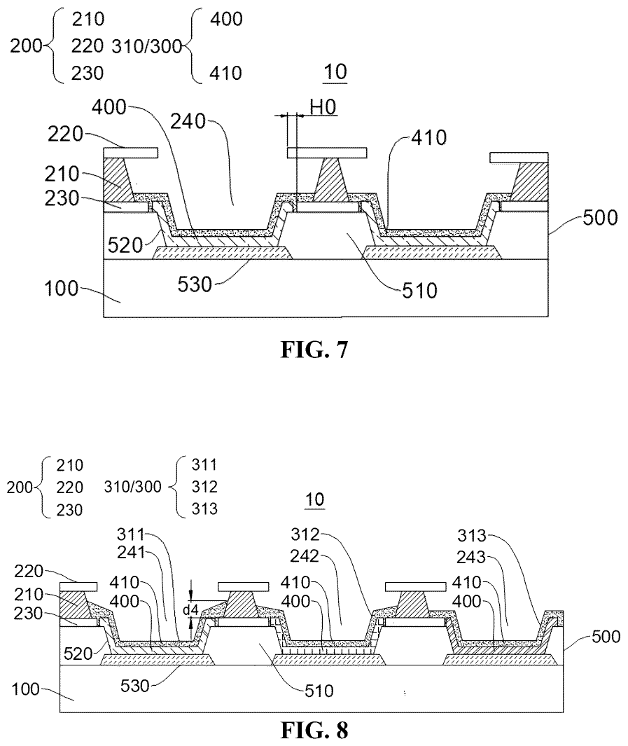

In an embodiment, at least two of the first width d1, second width d2, and third width d3 are different. Please refer to FIG. 7, which is a partial cross-sectional view of a display panel according to another embodiment.

As shown in FIG. 7, in one embodiment, a distance between an orthogonal projection of an edge of the third film layer 230 close to the light-emitting unit 310 on the substrate 100 and an orthogonal projection of an edge of the second film layer 220 close to the same light-emitting unit 310 on the substrate 100 is a protrusion length H0, and the protrusion lengths H0 corresponding to all light-emitting units 310 are the same.

Please refer to FIG. 8, which is a partial cross-sectional view of a display panel according to another embodiment.

As shown in FIG. 8, The second overlap widths d4 between the first electrode 410 and adjacent first film layer 210 of at least two light-emitting units 310 are different.

In an embodiment, the second overlap width d4 corresponding to the first light-emitting unit 311 is greater than or equal to the second overlap width d4 corresponding to the second light-emitting unit 312; in one embodiment, the second overlap width d4 corresponding to the second light-emitting unit 312 is greater than or equal to the second overlap width d4 corresponding to the third light-emitting unit 313; in one embodiment, at least two of the second overlap width d4 corresponding to the first light-emitting unit 311, the second overlap width d4 corresponding to the second light-emitting unit 312, and the second overlap width d4 corresponding to the third light-emitting unit 313 are different.

In an embodiment, the first electrodes 410 of a group of, i.e., some of, the light-emitting units 310 overlap with their adjacent first film layer 210, while the first electrodes 410 of another group, ex. other, of the light-emitting units 310 are spaced apart from their adjacent first film layer 210. In an embodiment, the first overlap width d0 is a dimension in a direction from an orthogonal projection of a sidewall of the third film layer 230 facing the isolation opening 240 on the substrate 100 toward an orthogonal projection of a sidewall of the first film layer 210 facing the isolation opening 240 on the substrate 100 in the overlapping portion.

In an embodiment, the second overlap width d4 is a dimension of the overlapping portion between the edge of the first electrode 410 and the first film layer 210 in a direction away from a surface of the third film layer 230 facing away from the substrate 100.

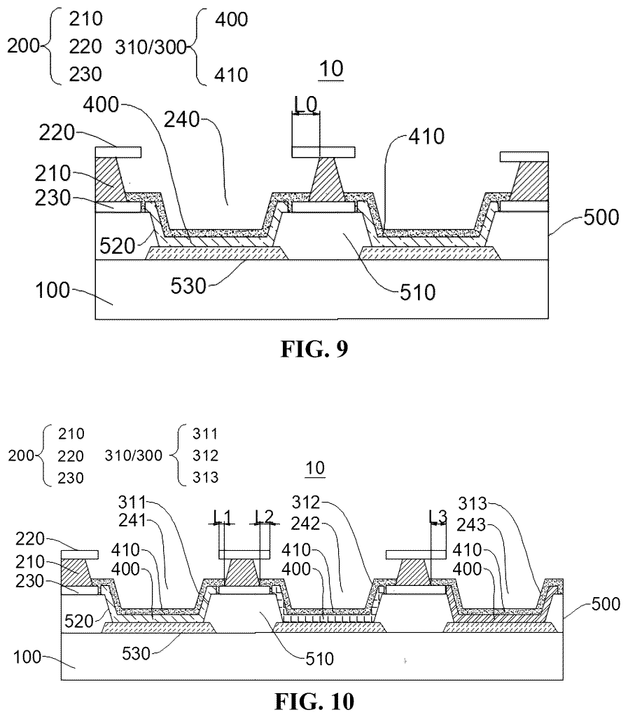

Please refer to FIG. 9, which is a partial cross-sectional view of a display panel according to another embodiment.

As shown in FIG. 9, in some embodiments, a distance between an orthogonal projection of an edge of the first film layer 210 close to the light-emitting unit 310 on a side away from the substrate on the substrate 100 and an orthogonal projection of an edge of the second film layer 220 close to the same light-emitting unit 310 on the substrate 100 is a first extension length L0, and the first extension length L0 is greater than or equal to 0.4 μm and less than or equal to 0.8 μm. For example, the extension length L0 can be 0.4 μm, 0.5 μm, 0.65 μm, 0.8 μm, etc.

In these embodiments, with the first extension length L0 being greater than or equal to 0.4 μm, it can improve the problem of carrier crosstalk between adjacent light-emitting units 310 that occurs when the first extension length L0 is too small, which would cause the light-emitting layer to connect with the isolation structure 200 after breaking at the edge of the isolation structure 200 and falling into the isolation opening 240. With the extension length L0 being less than or equal to 0.8 μm, it can alleviate the problem of the second film layer 220 being at risk of warping or breaking during the preparation process when the first extension length L0 is too large, causing the protruding dimension of the second film layer 220 relative to the first film layer 210 toward the isolation opening 240 to be too large, resulting in a large suspended portion of the second film layer 220.

In some embodiments, the light-emitting unit 310 includes a first light-emitting unit 311 and a second light-emitting unit 312, and the first extension length corresponding to the first light-emitting unit 311 is less than or equal to the first extension length corresponding to the second light-emitting unit 312.

In some embodiments, the light-emitting unit 310 further includes a third light-emitting unit 313, and the first extension length corresponding to the second light-emitting unit 312 is less than or equal to the first extension length corresponding to the third light-emitting unit 313.

In some embodiments, a distance between an orthogonal projection of an edge of the first film layer 210 close to the light-emitting unit 310 on a side close to the substrate 100 on the substrate 100 and an orthogonal projection of an edge of the second film layer 220 close to the same light-emitting unit 310 on the substrate 100 is a second extension length; the second extension lengths corresponding to at least two light-emitting units 310 are different.

In some embodiments, the second extension lengths corresponding to a plurality of light-emitting units 310 having the same light-emitting color are the same.

The second extension length corresponding to a light-emitting unit 310 refers to the distance between the edge of the orthogonal projection of the first film layer 210 close to the light-emitting unit 310 on the substrate 100 and the edge of the orthogonal projection of the second film layer 220 close to the same light-emitting unit 310 on the substrate 100.

In these embodiments, the first electrodes 410 corresponding to light-emitting units 310 of the same light-emitting color have the same second extension length with the third film layer 230 of the isolation structure 200, thereby ensuring similar or identical overlap impedance between these first electrodes 410 and the third film layer 230. Light-emitting units 310 of the same color have similar or identical light-emitting effects, improving the display uniformity of the display panel 10. When the overlap areas corresponding to light-emitting units 310 of the same color are the same, it becomes easier to compare the overlap areas between light-emitting units 310 of different colors.

Please refer to FIGS. 9 and 10, where FIG. 10 is a partial cross-sectional view of a display panel according to another embodiment.

As shown in FIGS. 9 and 10, in some embodiments, the light-emitting unit 310 includes a first light-emitting unit 311 and a second light-emitting unit 312, and the second extension length corresponding to the first light-emitting unit 311 is a first length L1, the second extension length corresponding to the second light-emitting unit 312 is a second length L2, and the first length L1 is less than or equal to the second length L2.

In these embodiments, the first length L1 is less than or equal to the second length L2. For example, the degree of recess of the first film layer 210 relative to the second film layer 220 in the direction away from the isolation opening 240 is different, with the first film layer 210 being more recessed on the side close to the second light-emitting unit 312 than on the side close to the first light-emitting unit 311. When preparing the first electrode 410, the peripheries of the first electrodes 410 corresponding to the first light-emitting unit 311 and the second light-emitting unit 312 overlap with the third film layer 230 of the isolation structure 200. The first electrode 410 corresponding to the second light-emitting unit 312 can have a larger area falling onto the third film layer 230, thereby reducing the overlap impedance between this portion of the first electrode 410 and the isolation structure 200, improving the light-emitting effect of the second light-emitting unit 312.

In some embodiments, the light-emitting unit 310 further includes a third light-emitting unit 313, and the second extension length corresponding to the third light-emitting unit 313 is a third length L3, and the second length L2 is less than or equal to the third length L3. At least two of the first length L1, second length L2, and third length L3 are different.

In these embodiments, the second length L2 is less than or equal to the third length L3. For example, the degree of recess of the first film layer 210 relative to the second film layer 220 in the direction away from the isolation opening 240 is different, with the first film layer 210 being more recessed on the side close to the third light-emitting unit 313 than on the side close to the second light-emitting unit 312. When preparing the first electrode 410, the peripheries of the first electrodes 410 corresponding to the second light-emitting unit 312 and the third light-emitting unit 313 overlap with the third film layer 230 of the isolation structure 200. The first electrode 410 corresponding to the third light-emitting unit 313 can have a larger area falling onto the third film layer 230, thereby reducing the overlap impedance between this portion of the first electrode 410 and the isolation structure 200, improving the light-emitting effect of the third light-emitting unit 313.

For example, the area of the orthogonal projection of the first film layer 210 on the substrate 100 is smaller than the area of the orthogonal projection of the second film layer 220 on the substrate 100.

For example, the area of an orthogonal projection of the first film layer 210 on the substrate 100 is smaller than the area of the orthogonal projection of the third film layer 230 on the substrate 100.

In an embodiment, the area of the orthogonal projection of the third film layer 230 on the substrate 100 is smaller than the area of the orthogonal projection of the second film layer 220 on the substrate 100.

In an embodiment, the first extension length L0 is a dimension by which the second film layer 220 protrudes beyond the first film layer 210 in a direction toward the isolation opening 240.

In an embodiment, the second extension length is a dimension by which the second film layer 220 protrudes beyond the first film layer 210 in a direction toward the isolation opening 240.

In some embodiments, the display panel 10 further includes: a pixel definition layer 500 disposed on the substrate 100, and the pixel definition layer 500 includes a pixel defining portion 510 and a pixel opening 520 formed by enclosing of the pixel defining portion 510, and the pixel opening 520 and the isolation opening 240 are communicatively connected.

In these embodiments, the pixel openings 520 encircled by the pixel defining portion 510 are used to define the light-emitting region of the display panel 10. The pixel opening 520 is communicatively connected with the isolation opening 240, reducing the blocking of the pixel opening 520 by the isolation structure 200 and ensuring the light-emitting effect of the display panel 10. In some embodiments, the isolation structure 200 is disposed on a side of the pixel defining portion 510 away from the substrate 100. In one embodiment, the pixel definition layer 500 has a recessed opening, and the isolation structure 200 is located in the recessed opening.

In these embodiments, the isolation structure 200 is disposed on the pixel defining portion 510, creating a large height difference relative to the pixel opening 520. The film layers forming the first electrode 410 and light-emitting portion 400 of the light-emitting unit are more likely to break at the position of the isolation structure 200, reducing the difficulty of preparing the light-emitting unit 310.

In some embodiments, the light-emitting unit 310 includes a second electrode 530, and the second electrode 530 is disposed between the substrate 100 and the pixel definition layer 500, and at least a portion of the second electrode 530 is exposed by the pixel opening 520. The second electrode 530 can be an anode.

In these embodiments, at least a portion of the second electrode 530 is exposed by the pixel opening 520, meaning that the orthogonal projection of the second electrode 530 on the substrate 100 and the orthogonal projection of the pixel opening 520 on the substrate 100 at least partially overlap, serving as an electrode of the light-emitting unit 310 to ensure the light emission of the light-emitting unit 310. One of the second electrode 530 and the first electrode 410 serves as the anode of the light-emitting unit 310, while the other serves as the cathode. In this embodiment, the second electrode 530 is exemplified as the anode of the light-emitting unit 310, and the first electrode 410 as the cathode.

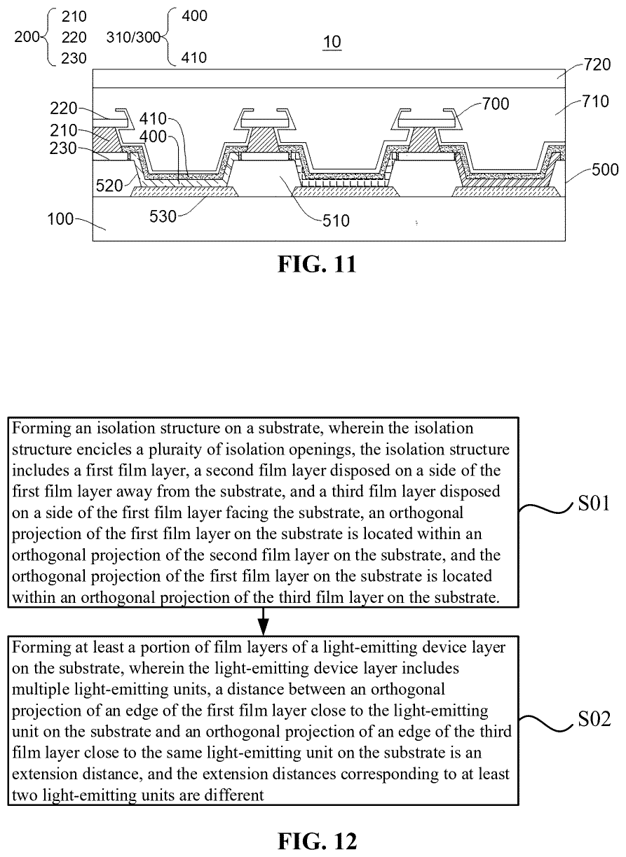

Please refer to FIG. 11, which is a partial cross-sectional view of a display panel according to another embodiment.

As shown in FIG. 11, in some embodiments, the display panel 10 further includes: a first encapsulation layer 700 disposed on a side of the light-emitting device layer 300 away from the substrate 100, and the first encapsulation layer 700 includes multiple encapsulation portions disposed on a side of corresponding light-emitting units 310 away from the substrate 100. In an embodiment, light-emitting units 310 having different light-emitting colors correspond to different encapsulation portions.

In these embodiments, at least a portion of the encapsulation portions of the first encapsulation layer 700 is disposed in the isolation opening 240 to encapsulate the light-emitting unit 310 in the isolation opening 240, reducing water and oxygen invasion into the light-emitting unit 310 and improving the service life of the light-emitting unit 310.

In an embodiment, the material of the first encapsulation layer 700 includes inorganic material, which has good density and good barrier properties against moisture and oxygen.

In an embodiment, the display panel 10 further includes: a second encapsulation layer 710 disposed on a side of the first encapsulation layer 700 away from the substrate 100.

In an embodiment, the display panel 10 further includes: a third encapsulation layer 720 disposed on a side of the second encapsulation layer 710 away from the substrate 100. The display panel 10 adopts a three-layer encapsulation structure, providing better encapsulation performance and reducing the possibility of water and oxygen invasion.

In an embodiment, the material of the second encapsulation layer 710 includes organic material.

In an embodiment, the material of the third encapsulation layer 720 includes inorganic material. The first encapsulation layer 700, second encapsulation layer 710, and third encapsulation layer 720 use inorganic material, organic material, and inorganic material respectively for encapsulation, forming a TFE (Thin Film Encapsulation) structure, further improving the encapsulation performance.

For example, the first film layer 210 includes conductive material.

In some embodiments, the second film layer 220 includes conductive material or insulating material.

In these embodiments, the second film layer 220 includes conductive material, for example, the second film layer 220 includes non-metallic conductive material or metallic conductive material. When the second film layer 220 is made of non-metallic conductive material or insulating material, during the wet etching process of the first film layer 210 using etchant, the second film layer 220 is difficult to be etched, making it easier for the first film layer 210 to achieve a recessed arrangement relative to the second film layer 220.

In some embodiments, both the first film layer 210 and the second film layer 220 include metal materials, and the materials of the first film layer 210 and the second film layer 220 are different.

In these embodiments, when both the first film layer 210 and the second film layer 220 are metal materials, an etchant can be used to wet etch the first film layer 210. Through the selection of the etchant, the etching rate of the second film layer 220 can be made smaller than that of the first film layer 210. Due to the higher etching rate of the first film layer 210, during wet etching with the etchant, even though the second film layer 220 will be etched to some extent, the first film layer 210 is etched faster, resulting in the first film layer 210 being recessed relative to the second film layer 220.

In an embodiment, the material of the second film layer 220 is titanium (Ti), the material of the first film layer 210 is aluminum (Al), and the material of the third film layer 230 is titanium nitride (TiN) or titanium or molybdenum nitride (MoN), making the isolation structure 200 a three-layer metal composite material of Ti/Al/TiN (titanium/aluminum/titanium nitride) or Ti/Al/Ti (titanium/aluminum/titanium) or Ti/Al/MoN (titanium/aluminum/molybdenum nitride). Compared to the solution where the third film layer 230 is molybdenum, the present application can reduce the dimension by which the second film layer 220 protrudes beyond the first film layer 210, thereby reducing the risk of warping of the second film layer 220 when this protrusion dimension is too large. In the solution where the third film layer 230 is molybdenum, when preparing light-emitting units 310 of different colors step by step, for example, during the preparation of the light-emitting portion 400 and first electrode 410 of the first color light-emitting unit 310, when wet etching the electrode material in the isolation openings 240 corresponding to light-emitting units 310 of other colors, the wet etching solution would etch away the portion of the third film layer 230 protruding beyond the first film layer 210. Therefore, after etching the electrode material and light-emitting material, it is necessary to perform side etching on the first film layer 210 in the isolation openings 240 corresponding to light-emitting units 310 of other colors using developer to make the third film layer 230 protrude beyond the first film layer 210. This leads to the second film layer 220 protruding too far beyond the first film layer 210, and the dimension of protrusion becomes larger for isolation openings 240 corresponding to light-emitting units 310 prepared later in the sequence, making them prone to warping or lifting.

In an embodiment, the light-emitting portion 400 includes an electron injection layer (EIL), an electron transport layer (ETL), a light-emitting material layer, a hole injection layer (HIL), and a hole transport layer (HTL).

As shown in FIGS. 1 to 11, the present application also provides a display panel 10, which includes: a substrate 100; an isolation structure 200 disposed on the substrate 100, a light-emitting device layer 300 disposed on the substrate 100, and the isolation structure 200 forms a plurality of isolation openings 240 by enclosing, the isolation structure 200 includes a first film layer 210, a second film layer 220 disposed on a side of the first film layer 210 away from the substrate 100, and a third film layer 230 disposed on a side of the first film layer 210 facing the substrate 100, an orthogonal projection of the first film layer 210 on the substrate 100 is located within an orthogonal projection of the second film layer 220 on the substrate 100, and the orthogonal projection of the first film layer 210 on the substrate 100 is located within an orthogonal projection of the third film layer 230 on the substrate 100. The light-emitting device layer 300 includes a plurality of light-emitting units 310, and at least a portion of the light-emitting unit is disposed in the isolation opening 240; the light-emitting unit includes a light-emitting portion 400 and a first electrode 410; the first electrode 410 is disposed on a side of the light-emitting portion 400 away from the substrate 100, and the first electrode 410 is electrically connected to the third film layer 230. An area where the first electrode 410 covers the third film layer 230 is an overlap area, and the overlap areas corresponding to the first electrodes 410 of at least two light-emitting units 310 are different. A width of an overlapping portion between an orthogonal projection of the first electrode 410 on the substrate 100 and an orthogonal projection of the third film layer 230 on the substrate 100 is a first overlap width d0, and the first overlap widths d0 corresponding to the first electrodes 410 of at least two light-emitting units 310 are different.

According to the embodiments of the present application, the display panel 10 includes a substrate 100, an isolation structure 200, and a light-emitting device layer 300. The first film layer 210, second film layer 220, and third film layer 230 are arranged to form the isolation structure 200, and the first film layer 210 arranged close to the substrate 100 has an orthogonal projection on the substrate 100 that is located within the orthogonal projection of the second film layer 220 on the substrate 100. The area of the second film layer 220 is larger than that of the first film layer 210, and the second film layer 220 covers the surface of the first film layer 210 close to the second film layer 220, causing the first film layer 210 to be recessed relative to the second film layer 220 in a direction away from the isolation opening 240. When forming the light-emitting material layer and electrode material layer of the light-emitting device layer 300, these layers produce a large height difference at the edge of the isolation structure 200, and since the first film layer 210 is recessed relative to the second film layer 220, these layers are difficult to connect at the edge of the isolation structure 200, resulting in breakage. The breakage of the light-emitting material layer and electrode material layer forms separated light-emitting portions 400 and first electrodes 410, thereby reducing carrier crosstalk within the light-emitting material layer and improving the display effect of the display panel 10. Moreover, the preparation of light-emitting units 310 does not require precise masks, reducing the development and use of precise masks and lowering production costs. The overlap areas corresponding to at least two light-emitting units 310 are different, with some light-emitting units 310 having larger overlap areas with the isolation structure 200. When preparing the first electrode 410, the periphery of the first electrode 410 overlaps with the third film layer 230 of the isolation structure 200, and some light-emitting units 310 have larger overlap areas between their first electrodes 410 and the third film layer 230 of the isolation structure 200, thereby reducing the overlap impedance between these first electrodes 410 and the isolation structure 200, improving the light-emitting effect of the light-emitting units 310 and the performance of the display panel 10.

This embodiment can be combined with part or all of the features in the above embodiments. The structural design in this embodiment can be applied to other display panels 10, and specific choices can be made according to actual situations, without specific limitations by this application.

The present application also provides a display device that includes the display panel 10 according to any of the above embodiments. Since the display device provided by the embodiments of the present application includes the display panel 10 according to any of the above embodiments, the display device has the beneficial effects of the display panel 10, which will not be repeated here.

The display device in the embodiments of the present application includes but is not limited to devices with display functions such as mobile phones, Personal Digital Assistants (PDA), tablet computers, e-books, televisions, access control systems, smart fixed telephones, consoles, etc.

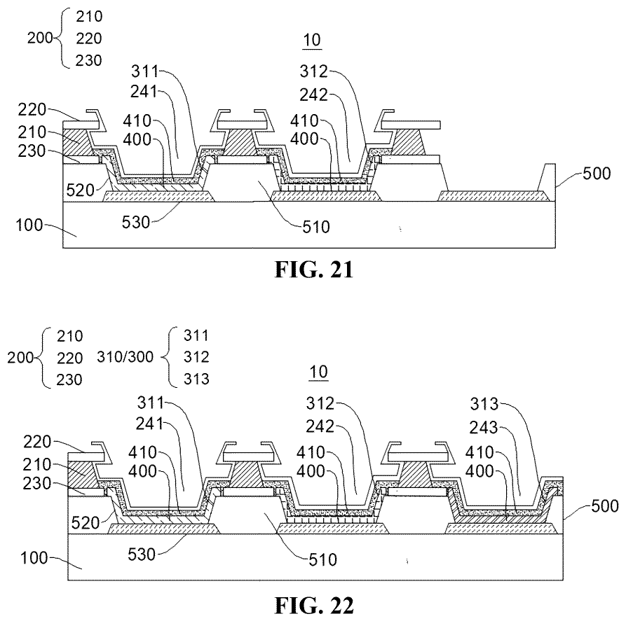

Please refer to FIGS. 1 to 22, where FIG. 12 is a flow diagram of a method for preparing a display panel according to an embodiment of the present application; FIGS. 12 to 22 are process diagrams for preparing a display panel according to an embodiment of the present application.

The present application also provides a method for preparing a display panel 10, which can be any of the display panels 10 provided in the above embodiments. As shown in FIGS. 1 to 22, the preparation method includes:
Step S01: Forming an isolation structure on a substrate, and the isolation structure encircles one or more isolation openings, the isolation structure includes a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate.
Step S02: Forming at least a portion of film layers of a light-emitting device layer on the substrate, and the light-emitting device layer includes a plurality of light-emitting units, a distance between an orthogonal projection of an edge of the first film layer close to the light-emitting unit on the substrate and an orthogonal projection of an edge of the third film layer close to the same light-emitting unit on the substrate is an extension distance, and the extension distances corresponding to at least two light-emitting units are different.

According to the preparation method of the present application, through Step S01, the isolation structure 200 is formed, where the first film layer 210, second film layer 220, and third film layer 230 are arranged to form the isolation structure 200. The first film layer 210 arranged close to the substrate 100 has an orthogonal projection on the substrate 100 that is located within the orthogonal projection of the second film layer 220 on the substrate 100. The area of the second film layer 220 is larger than that of the first film layer 210, and the second film layer 220 covers the surface of the first film layer 210 close to the second film layer 220, causing the first film layer 210 to be recessed relative to the second film layer 220 in a direction away from the isolation opening 240. Through Step S02, when forming the light-emitting material layer of the light-emitting device layer 300, the light-emitting material layer produces a large height difference at the edge of the isolation structure 200, and since the first film layer 210 is recessed relative to the second film layer 220, the light-emitting material layer is difficult to connect at the edge of the isolation structure 200, resulting in breakage. The breakage of the light-emitting material layer forms separated light-emitting portions, thereby reducing carrier crosstalk within the light-emitting material layer and improving the display effect of the display panel 10. Moreover, the preparation of light-emitting units 310 does not require precise masks, reducing the development and use of precise masks and reducing production costs. The extension distances D0 corresponding to at least two light-emitting units 310 are different. When preparing the first electrode 410, the periphery of the first electrode 410 overlaps with the third film layer 230 of the isolation structure 200, and some light-emitting units 310 correspond to larger extension distances D0 of the isolation structure 200, making the overlap area between the first electrode 410 and the third film layer 230 of the isolation structure 200 larger, thereby reducing the overlap impedance between these first electrodes 410 and the isolation structure 200, improving the light-emitting effect of the light-emitting units 310 and the performance of the display panel 10.

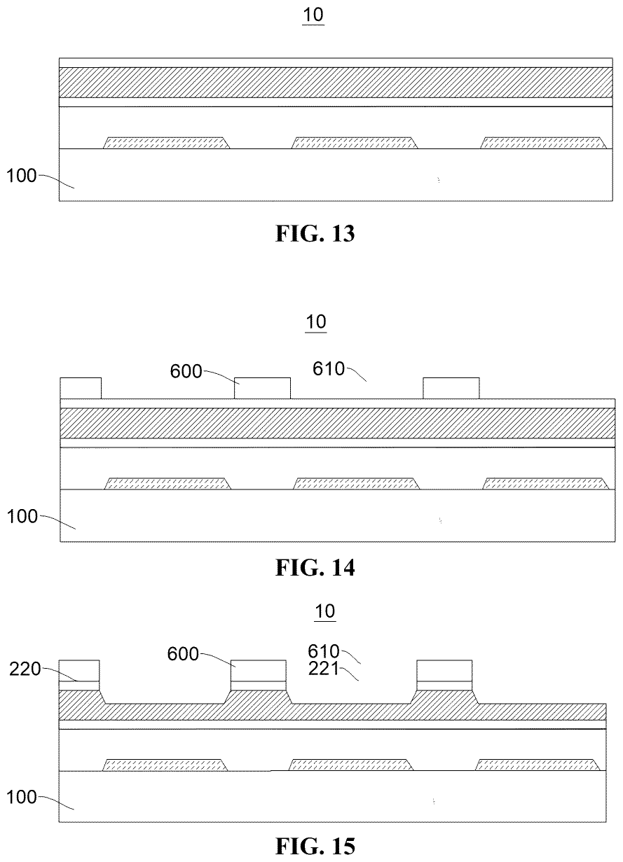

In some embodiments, in Step S01, the method further includes:
Forming an isolation material layer on the substrate 100, and the isolation material layer includes a third material layer, a first material layer, and a second material layer sequentially stacked in a direction away from the substrate 100, as shown in FIG. 13;
Forming a first barrier layer 600 having a plurality of first openings 610 on a side of the isolation material layer away from the substrate 100, as shown in FIG. 14;
Patterning the isolation material layer through the first openings 610 to form a second film layer 220 having second openings 221 from the second material layer; and the second openings 221 are a part of the isolation openings 240, as shown in FIG. 15.

Patterning the first material layer through the second openings 221 to form a first film layer 210, and the orthogonal projection of the first film layer 210 on the substrate 100 is located within the orthogonal projection of the second film layer 220 on the substrate 100.

In these embodiments, by setting up the first barrier layer 600 having first openings 610 to partially cover the isolation material layer, it achieves etching blocking protection for portions that do not need to be etched, and then patterns the isolation material layer through the first openings 610, removing part of the second material layer to form the second film layer 220 having second openings 221. After forming the second openings 221, the first material layer can be further patterned through the second openings 221 to form the first film layer 210. The first film layer 210 arranged close to the substrate 100 has an orthogonal projection on the substrate 100 that is located within the orthogonal projection of the second film layer 220 on the substrate 100. The area of the second film layer 220 is larger than that of the first film layer 210, and the second film layer 220 covers the surface of the first film layer 210 close to the second film layer 220, causing the first film layer 210 to be recessed relative to the second film layer 220 in a direction away from the isolation opening 240. When forming the light-emitting material layer and electrode material layer of the light-emitting device layer 300, these layers produce a large height difference at the edge of the isolation structure 200, and since the first film layer 210 is recessed relative to the second film layer 220, these layers are difficult to connect at the edge of the isolation structure 200, resulting in breakage. The breakage of the electrode material layer forms separated first electrodes 410, and the breakage of the light-emitting material layer forms separated light-emitting portions 400, thereby reducing carrier crosstalk within the light-emitting portions 400 and improving the display effect of the display panel 10. Moreover, the preparation of light-emitting units 310 does not require precise masks, reducing the development and use of precise masks and reducing production costs.

In an embodiment, in the step of patterning the isolation material layer through the first openings 610 to form the second film layer 220, both the second material layer exposed by the first openings 610 and part of the first material layer are removed. When patterning the second material layer, part of the first material layer is simultaneously etched, as shown in FIG. 15. For example, grooves connecting with the second openings 221 and first openings 610 are formed in the first material layer, causing the first material layer to be etched and recessed, facilitating subsequent wet etching. For example, in this step, the first material layer is not completely etched through, and the grooves do not penetrate through the first material layer.

In an embodiment, in the step of patterning the isolation material layer through the first openings 610 to form the second film layer 220, a dry etching process is used to pattern the isolation material layer through the first openings 610 to form the second film layer 220 having second openings 221. The dry etching process can better remove the second material layer, avoiding residue of the second material layer in the first opening 610 area that would affect subsequent etching of the first material layer.

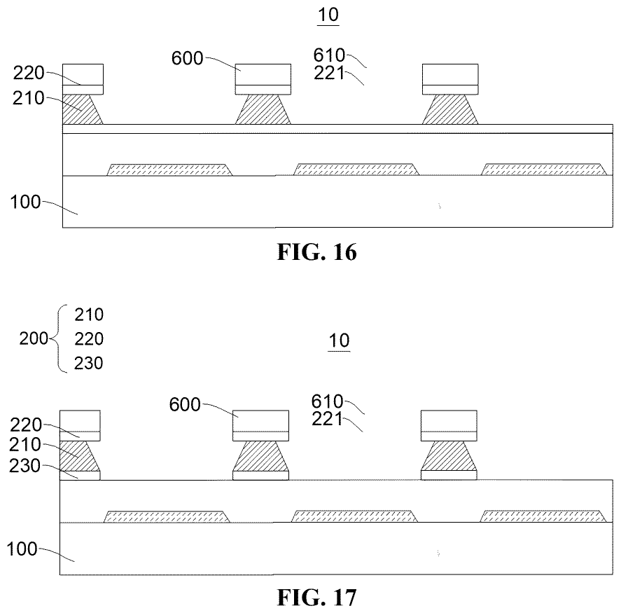

In an embodiment, in the step of patterning the first material layer through the second openings 221 to form the first film layer 210, a wet etching process is used. The wet etching process can better remove the first material layer, ensuring that the orthogonal projection of the formed first film layer 210 on the substrate 100 can be located within the orthogonal projection of the second film layer 220 on the substrate 100, as shown in FIG. 16. For example, in this step, the first material layer is completely etched through, and the grooves penetrate through the first material layer. For example, the area of the orthogonal projection of the first film layer 210 on the substrate 100 is smaller than the area of the orthogonal projection of the second film layer 220 on the substrate 100.

In an embodiment, the material of the first barrier layer 600 includes photoresist, which is easily obtainable and provides good etching blocking effect.

In an embodiment, the third material layer has greater etching resistance to the etchant used in the wet etching process than the first material layer has to the etchant used in the wet etching process.

In some embodiments, after the step of patterning the first material layer through the second openings 221 to form the first film layer 210, the method further includes:
Patterning the third material layer through the first openings 610 to form a third film layer 230, as shown in FIG. 17.

In these embodiments, after wet etching the first material layer, the third material layer is exposed by the first openings 610, allowing the third material layer to be etched through the first openings 610 to remove the third material layer in the first opening 610 area, forming the third film layer 230, and when subsequently preparing the first electrode 410, the first electrode 410 can overlap with the third film layer 230.

In an embodiment, in the step of patterning the third material layer through the first openings 610, a dry etching process is used to pattern the third material layer through the first openings 610 to form the third film layer 230. Since the third material layer is wet etching-resistant material, the dry etching process can better remove the third material layer to form the third film layer 230.

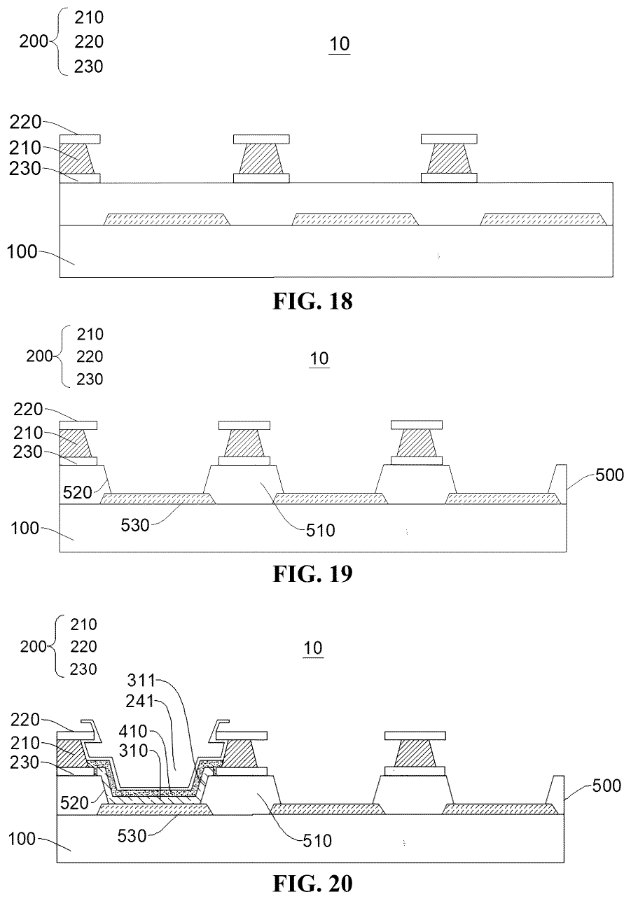

In an embodiment, after the step of patterning the third material layer through the first openings 610 to form the third film layer 230, the method further includes:
Patterning the first film layer 210 to make the orthogonal projection of the first film layer 210 on the substrate 100 located within the orthogonal projection of the third film layer 230 on the substrate 100; the area of the orthogonal projection of the first film layer 210 on the substrate 100 is smaller than the area of the orthogonal projection of the third film layer 230 on the substrate 100, as shown in FIG. 18.

In these embodiments, after forming the third film layer 230, the first film layer 210 is further patterned to make it retract inward relative to the third film layer 230 in a direction away from the isolation opening 240, gradually exposing the surface of the third film layer 230 away from the substrate 100, facilitating subsequent overlap between the third film layer 230 and the first electrode 410.

In an embodiment, in the step of patterning the first film layer 210 to make the orthogonal projection of the first film layer 210 on the substrate 100 located within the orthogonal projection of the third film layer 230 on the substrate 100, a wet etching process is used. The wet etching process can better remove the first film layer 210, ensuring that orthogonal projection of the first film layer 210 on the substrate 100 can be located within the orthogonal projection of the third film layer 230 on the substrate 100.

In an embodiment, after patterning the first film layer 210 to make the orthogonal projection of the first film layer 210 on the substrate 100 located within the orthogonal projection of the third film layer 230 on the substrate 100, the pixel definition layer 500 is patterned to form pixel openings 520.

In an embodiment, the second electrode 530 can be formed before preparing the isolation structure 200.

In some embodiments, the isolation opening 240 includes a first isolation opening 241 and a second isolation opening 242, or includes a first isolation opening 241, a second isolation opening 242, and a third isolation opening 243. In the step of forming at least a portion of film layers of the light-emitting device layer 300 on the substrate 100, the method further includes:
Sequentially forming a first light-emitting material layer, a first electrode material layer, and a first encapsulation material layer on the substrate 100 (for example, the first light-emitting material layer, first electrode material layer, and first encapsulation material layer can cover the first isolation opening 241, second isolation opening 242, and third isolation opening 243);
Patterning the first light-emitting material layer, first electrode material layer, and first encapsulation material layer to form a light-emitting portion 400, first electrode 410 of the first light-emitting unit 311 corresponding to the first isolation opening 241, and a first encapsulation portion disposed on a side of the first light-emitting unit 311 away from the substrate 100. In this step, etching the first light-emitting material layer, first electrode material layer, and first encapsulation material layer in the second isolation opening 242 and/or third isolation opening 243.

In these embodiments, at least a portion of the first light-emitting unit 311 is disposed in the first isolation opening 241, achieving light emission in the first isolation opening 241 area; the first electrode 410 serves as an electrode for the light-emitting portion 400 of the first light-emitting unit 311, driving the light emission of the first light-emitting unit 311; the first encapsulation portion is disposed on a side of the first light-emitting unit 311 away from the substrate 100 to achieve encapsulation of the first light-emitting unit 311.

In some embodiments, after the step of forming the light-emitting portion 400, first electrode 410 of the first light-emitting unit 311, and the first encapsulation portion, the method further includes:
Sequentially forming a second light-emitting material layer, a second electrode material layer, and a second encapsulation material layer on the substrate 100 (for example, the second light-emitting material layer, second electrode material layer, and second encapsulation material layer can cover the first isolation opening 241, second isolation opening 242, and third isolation opening 243);
Patterning the second light-emitting material layer, second electrode material layer, and second encapsulation material layer to form a light-emitting portion 400, first electrode 410 of the second light-emitting unit 312 corresponding to the second isolation opening 242, and a second encapsulation portion disposed on a side of the second light-emitting unit 312 away from the substrate 100. In this step, etching the second light-emitting material layer, second electrode material layer, and second encapsulation material layer in the first isolation opening 241 and/or third isolation opening 243.

In these embodiments, at least a portion of the second light-emitting unit 312 is disposed in the second isolation opening 242, achieving light emission in the second isolation opening 242 area; the second encapsulation portion is disposed on a side of the second light-emitting unit 312 away from the substrate 100 to achieve encapsulation of the second light-emitting unit 312.

In some embodiments, the isolation opening 240 further includes a third isolation opening 243. After the step of forming the light-emitting portion 400, first electrode 410 of the second light-emitting unit 312, and the second encapsulation portion, the method further includes:
Sequentially forming a third light-emitting material layer, a third electrode material layer, and a third encapsulation material layer on the substrate 100 (for example, the third light-emitting material layer, third electrode material layer, and third encapsulation material layer can cover the first isolation opening 241, second isolation opening 242, and third isolation opening 243);
Patterning the third light-emitting material layer, third electrode material layer, and third encapsulation material layer to form a light-emitting portion 400, first electrode 410 of the third light-emitting unit 313 corresponding to the third isolation opening 243, and a third encapsulation portion disposed on a side of the third light-emitting unit 313 away from the substrate 100. In this step, etching the second light-emitting material layer, second electrode material layer, and second encapsulation material layer in the first isolation opening 241 and second isolation opening 242.

In these embodiments, at least a portion of the third light-emitting unit 313 is disposed in the third isolation opening 243, achieving light emission in the third isolation opening 243 area; the third encapsulation portion is disposed on a side of the third light-emitting unit 313 away from the substrate 100 to achieve encapsulation of the third light-emitting unit 313.

In some embodiments, in the step of patterning the first light-emitting material layer, first electrode material layer, and first encapsulation material layer, the method further includes:
Dry etching the first encapsulation material layer to form the first encapsulation portion;
Wet etching the first electrode material layer to form the first electrode 410 of the first light-emitting unit 311.

In these embodiments, dry etching is used to remove portions of the first encapsulation material layer except in the first isolation opening 241 to form the first encapsulation portion in the first isolation opening 241; wet etching is used to remove portions of the first electrode material layer except in the first isolation opening 241 to form the first electrode 410 in the first isolation opening 241. In this step, using wet etching process, when the wet etchant enters the second isolation opening 242 and third isolation opening 243, it etches the inner walls of the first film layer 210 facing these openings, to increase the extension distance D0 of the isolation structure 200 toward the second isolation opening 242 and third isolation opening 243.

In some embodiments, in the step of patterning the second light-emitting material layer, second electrode material layer, and second encapsulation material layer, the method further includes:
Dry etching the second encapsulation material layer to form the second encapsulation portion;
Wet etching the second electrode material layer to form the first electrode 410 of the second light-emitting unit 312.

In these embodiments, dry etching is used to remove portions of the second encapsulation material layer except in the second isolation opening 242 to form the second encapsulation portion; wet etching is used to remove portions of the second electrode material layer except in the second isolation opening 242 to form the first electrode 410. In this step, using wet etching process, when the wet etchant enters the third isolation opening 243, it etches the inner wall of the first film layer 210 facing the third isolation opening 243, thereby further increasing the extension distance D0 of the isolation structure 200 toward the third isolation opening 243. The extension distance corresponding to the first light-emitting unit is a first distance, the extension distance corresponding to the second light-emitting unit is a second distance, and the first distance is less than the second distance. The extension distance corresponding to the third light-emitting unit is a third distance, and the second distance is less than the third distance.

In some embodiments, in the step of patterning the third light-emitting material layer, third electrode material layer, and third encapsulation material layer, the method further includes:
Dry etching the third encapsulation material layer to form the third encapsulation portion;
Wet etching the third electrode material layer to form the first electrode 410 of the third light-emitting unit 313.

In these embodiments, dry etching is used to remove portions of the third encapsulation material layer except in the third isolation opening 243 to form the third encapsulation portion; wet etching is used to remove portions of the third electrode material layer except in the third isolation opening 243 to form the first electrode 410 in the third isolation opening 243.

In an embodiment, at least two of the first isolation opening 241, second isolation opening 242, and third isolation opening 243 can be prepared at different times.

For example, first preparing the first isolation opening 241 and second isolation opening 242, then preparing the light-emitting portion 400, first electrode 410, and first encapsulation portion of the first light-emitting unit 311, then preparing the light-emitting portion 400, first electrode 410, and second encapsulation portion of the second light-emitting unit 312, then preparing the third isolation opening 243, and finally preparing the light-emitting portion 400, first electrode 410, and third encapsulation portion of the third light-emitting unit 313. The extension distance D0, first overlap width d0, first extension length, second extension length, and second overlap width d4 corresponding to the first light-emitting unit 311 and second light-emitting unit 312 are different. The extension distance D0, first overlap width d0, first extension length, second extension length, and second overlap width d4 corresponding to the first light-emitting unit 311 and third light-emitting unit 313 are the same.

For example, first preparing the first isolation opening 241, then preparing the light-emitting portion 400, first electrode 410, and first encapsulation portion of the first light-emitting unit 311, then preparing the second isolation opening 242 and third isolation opening 243, then preparing the light-emitting portion 400, first electrode 410, and second encapsulation portion of the second light-emitting unit 312, and finally preparing the light-emitting portion 400, first electrode 410, and third encapsulation portion of the third light-emitting unit 313. The extension distance D0, first overlap width d0, first extension length, second extension length, and second overlap width d4 corresponding to the second light-emitting unit 312 and third light-emitting unit 313 are different. The extension distance D0, first overlap width d0, first extension length, second extension length, and second overlap width d4 corresponding to the first light-emitting unit 311 and second light-emitting unit 312 are the same.

It should be understood that various forms of processes shown above can be used, with steps reordered, added, or deleted. For example, the steps recorded in this application can be executed in parallel, in sequence, or in different orders, as long as they can achieve the desired results of the embodiments of this application, which is not limited herein.

The above specific embodiments do not constitute limitations on the scope of protection of this application. It is understood that according to design requirements and other factors, various modifications, combinations, sub-combinations, and substitutions can be made. Any modifications, equivalent substitutions, and improvements made within the spirit and principles of this application should be included within the scope of protection of this application.

It should be noted that the display apparatus according to the embodiments of the present disclosure has the beneficial effects of the display panel according to any of the previous embodiments, and the reference should be made to the previous description of the beneficial effects of the display panel for the specific, which is not repeated in the embodiments of the present disclosure.

What is claimed is:

1. A display panel, comprising:
a substrate;
an isolation structure, disposed on the substrate, the isolation structure encircling one or more isolation openings, the isolation structure comprising a first film layer, a second film layer disposed on a side of the first film layer away from the substrate, and a third film layer disposed on a side of the first film layer facing the substrate, an orthogonal projection of the first film layer on the substrate being located within an orthogonal projection of the second film layer on the substrate, and the orthogonal projection of the first film layer on the substrate being located within an orthogonal projection of the third film layer on the substrate; and
a light-emitting device layer, disposed on the substrate, the light-emitting device layer comprising a plurality of light-emitting units, and at least a portion of the light-emitting unit being disposed in the isolation opening,
wherein a distance between an orthogonal projection of an edge of the first film layer close to the light-emitting unit on the substrate and an orthogonal projection of an edge of the third film layer close to the same light-emitting unit on the substrate is an extension distance, and the extension distances corresponding to at least two of the light-emitting units are different.

2. The display panel according to claim 1, wherein the material of the third film layer includes at least one of titanium nitride, titanium, and molybdenum nitride;
the first film layer includes a conductive material;
the second film layer includes a conductive material or an insulating material;
both the first film layer and the second film layer include metal materials, and the materials of the first film layer and the second film layer are different.

3. The display panel according to claim 1, wherein the extension distances corresponding to a plurality of light-emitting units having the same light-emitting color are the same;
the extension distance is a dimension by which the third film layer protrudes beyond the first film layer in a direction toward the isolation opening.

4. The display panel according to claim 1, wherein the light-emitting units comprise a first light-emitting unit and a second light-emitting unit, the extension distance corresponding to the first light-emitting unit is a first distance, the extension distance corresponding to the second light-emitting unit is a second distance, and the first distance is less than or equal to the second distance;
the first light-emitting unit and the second light-emitting unit have different light-emitting colors.

5. The display panel according to claim 4, wherein the light-emitting units further comprise a third light-emitting unit, the extension distance corresponding to the third light-emitting unit is a third distance, and the second distance is less than or equal to the third distance;
the first light-emitting unit, the second light-emitting unit, and the third light-emitting unit have different light-emitting colors; at least two of the first distance, the second distance, and the third distance are different.

6. The display panel according to claim 1, wherein the light-emitting unit comprises a light-emitting portion and a first electrode, wherein the first electrode is disposed on a side of the light-emitting portion away from the substrate, and the first electrode is electrically connected to the isolation structure;
in the same light-emitting unit, an orthogonal projection of the light-emitting portion on the substrate is located within an orthogonal projection of the first electrode on the substrate;
the light-emitting portion and the isolation structure are spaced apart;
the first electrode and the third film layer are electrically connected; and
in the same light-emitting unit, an area of an orthogonal projection of the light-emitting portion on the substrate is smaller than another area of an orthogonal projection of the first electrode on the substrate.

7. The display panel according to claim 6, wherein an area where the first electrode covers the third film layer is an overlap area, and the overlap areas corresponding to the first electrodes of at least two light-emitting units are different; and
the overlap areas corresponding to the light-emitting units having the same light-emitting color are the same.

8. The display panel according to claim 7, wherein the light-emitting units comprise a first light-emitting unit and a second light-emitting unit, the overlap area corresponding to the first light-emitting unit is a first area, the overlap area corresponding to the second light-emitting unit is a second area, and the first area is less than or equal to the second area; and
the first light-emitting unit and the second light-emitting unit have different light-emitting colors.

9. The display panel according to claim 8, wherein the light-emitting units further comprise a third light-emitting unit, the overlap area corresponding to the third light-emitting unit is a third area, and the second area is less than or equal to the third area;
the first light-emitting unit, the second light-emitting unit, and the third light-emitting unit have different light-emitting colors, and at least two of the first area, the second area, and the third area are different.

10. The display panel according to claim 6, wherein a width of an overlapping portion between an orthogonal projection of the first electrode on the substrate and an orthogonal projection of the third film layer on the substrate is a first overlap width, and the first overlap widths corresponding to the first electrodes of at least two light-emitting units are different.

11. The display panel according to claim 10, wherein the first overlap widths corresponding to the light-emitting units having the same light-emitting color are the same;
the light-emitting units comprise a first light-emitting unit and a second light-emitting unit, wherein the first overlap width corresponding to the first light-emitting unit is a first width, the first overlap width corresponding to the second light-emitting unit is a second width, and the first width is less than or equal to the second width;
the light-emitting units further comprises a third light-emitting unit, wherein the first overlap width corresponding to the third light-emitting unit is a third width, and the second width is less than or equal to the third width;
at least two of the first width, the second width, and the third width are different;
the second overlap widths between the first electrode and adjacent first film layer of at least two light-emitting units are different;
the second overlap widths corresponding to the first light-emitting unit is greater than or equal to the second overlap width corresponding to the second light-emitting unit;
the second overlap width corresponding to the second light-emitting unit is greater than or equal to the second overlap width corresponding to the third light-emitting unit;
at least two of the second overlap width corresponding to the first light-emitting unit, the second overlap width corresponding to the second light-emitting unit, and the second overlap width corresponding to the third light-emitting unit are different;
or, the first electrodes of a group of the light-emitting units overlap with the adjacent first film layer, and the first electrodes of another group of the light-emitting units are spaced apart from the adjacent first film layer;
the first overlap width is a dimension in a direction from an orthogonal projection of a sidewall of the third film layer facing the isolation opening on the substrate toward an orthogonal projection of a sidewall of the first film layer facing the isolation opening on the substrate in the overlapping portion;
the second overlap width is a dimension of the overlapping portion between the edge of the first electrode and the first film layer in a direction away from a surface of the third film layer facing away from the substrate.

12. The display panel according to claim 1, wherein a distance between an orthogonal projection of an edge of the third film layer close to the light-emitting unit on the substrate and an orthogonal projection of an edge of the second film layer close to the same light-emitting unit on the substrate is a protrusion length, and the protrusion lengths corresponding to the plurality of light-emitting units are the same.

13. The display panel according to claim 1, wherein a distance between an orthogonal projection of an edge of the first film layer close to the light-emitting unit on a side away from the substrate on the substrate and an orthogonal projection of an edge of the second film layer close to the same light-emitting unit on the substrate is a first extension length, and the first extension length is greater than or equal to 0.4 μm and less than or equal to 0.8 μm.

14. The display panel according to claim 1, wherein a distance between an orthogonal projection of an edge of the first film layer close to the light-emitting unit on a side close to the substrate on the substrate and an orthogonal projection of an edge of the second film layer close to the same light-emitting unit on the substrate is a second extension length; the second extension lengths corresponding to at least two light-emitting units are different;
the second extension lengths corresponding to the plurality of light-emitting units having the same light-emitting color are the same;
the light-emitting unit comprises a first light-emitting unit and a second light-emitting unit, wherein the second extension length corresponding to the first light-emitting unit is a first length, the second extension length corresponding to the second light-emitting unit is a second length, and the first length is less than or equal to the second length;
the light-emitting unit further comprises a third light-emitting unit, wherein the second extension length corresponding to the third light-emitting unit is a third length, and the second length is less than or equal to the third length;
at least two of the first length, the second length, and the third length are different;
an area of an orthogonal projection of the first film layer on the substrate is smaller than an area of an orthogonal projection area of the second film layer on the substrate, and the area of the orthogonal projection of the first film layer on the substrate is smaller than the area of the orthogonal projection of the third film layer on the substrate;
the area of the orthogonal projection of the third film layer on the substrate is smaller than the area of the orthogonal projection of the second film layer on the substrate;
the second extension length is a dimension by which the second film layer protrudes beyond the first film layer in a direction toward the isolation opening.

15. The display panel according to claim 1, further comprising a pixel definition layer disposed on the substrate, wherein the pixel definition layer comprises a pixel defining portion and a pixel opening encircled by the pixel defining portion, the pixel opening are communicated with the isolation opening;
the isolation structure is disposed on a side of the pixel defining portion away from the substrate;
the light-emitting unit comprises a second electrode, wherein the second electrode is disposed between the substrate and the pixel definition layer, and at least a portion of the second electrode is exposed from the pixel opening;
the display panel further comprises a first encapsulation layer disposed on a side of the light-emitting unit away from the substrate, wherein the first encapsulation layer comprises a plurality of encapsulation portions disposed on a side of corresponding light-emitting units away from the substrate;
the light-emitting units having different light-emitting colors correspond to different encapsulation portions;
the material of the first encapsulation layer comprises an inorganic material;
the display panel further comprises:
a second encapsulation layer disposed on a side of the first encapsulation layer away from the substrate;
a third encapsulation layer disposed on a side of the second encapsulation layer away from the substrate;
the material of the second encapsulation layer comprises an organic material;
the material of the third encapsulation layer comprises an inorganic material.

16. A display panel, comprising:
a substrate;
an isolation structure, disposed on the substrate, wherein the isolation structure encircles a plurality of isolation openings, the isolation structure comprises a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate;
a light-emitting device layer, disposed on the substrate, wherein the light-emitting device layer comprise a plurality of light-emitting units, and at least a portion of the light-emitting unit is disposed in the isolation opening; the light-emitting unit comprises a light-emitting portion and a first electrode; the first electrode is disposed on a side of the light-emitting portion away from the substrate, and the first electrode is electrically connected to the third film layer;
wherein an area where the first electrode covers the third film layer is an overlap area, and the overlap areas corresponding to the first electrodes of at least two light-emitting units are different; and
a width of an overlapping portion between an orthogonal projection of the first electrode on the substrate and an orthogonal projection of the third film layer on the substrate is a first overlap width, and the first overlap widths corresponding to the first electrodes of at least two light-emitting units are different.

17. A method for preparing a display panel, comprising:
forming an isolation structure on a substrate, wherein the isolation structure encircles a plurality of isolation openings, the isolation structure comprises a plurality of film layers having a first film layer, a second film layer disposed on a side of the first film layer away from the substrate, and a third film layer disposed on a side of the first film layer facing the substrate, an orthogonal projection of the first film layer on the substrate is located within an orthogonal projection of the second film layer on the substrate, and the orthogonal projection of the first film layer on the substrate is located within an orthogonal projection of the third film layer on the substrate;
forming at least a portion of the film layers of a light-emitting device layer on the substrate, wherein the light-emitting device layer includes a plurality of light-emitting units, a distance between an orthogonal projection of an edge of the first film layer close to the light-emitting unit on the substrate and an orthogonal projection of an edge of the third film layer close to the same light-emitting unit on the substrate is an extension distance, and the extension distances corresponding to at least two light-emitting units are different.

18. The method according to claim 17, wherein in the step of forming the isolation structure on the substrate, the method further comprises:
forming an isolation material layer on the substrate, wherein the isolation material layer comprises a third material layer, a first material layer, and a second material layer sequentially stacked in a direction away from the substrate;
forming a first barrier layer having a plurality of first openings on a side of the isolation material layer away from the substrate;
patterning the isolation material layer through the first openings, to form a second film layer having a plurality of second openings from the second material layer; wherein the second openings are a part of the isolation openings; patterning the first material layer through the second openings to form a first film layer, wherein the orthogonal projection of the first film layer on the substrate is located within the orthogonal projection of the second film layer on the substrate; the area of the orthogonal projection of the first film layer on the substrate is smaller than the area of the orthogonal projection of the second film layer on the substrate;
in the step of patterning the isolation material layer through the first openings to form the second film layer, removing the second material layer exposed by the first openings and a portion of the first material layer;
in the step of patterning the isolation material layer through the first openings to form the second film layer, patterning the isolation material layer through the first openings, by a dry etching process, to form the second film layer having the second openings from the second material layer;
in the step of patterning the first material layer through the second openings to form the first film layer, patterning the first material layer through the second openings, by a wet etching process, to form the first film layer;
the material of the first barrier layer comprises photoresist;
the third material layer has greater etching resistance to the etchant used in the wet etching process than the first material layer has to the etchant used in the wet etching process.

19. The method according to claim 18, wherein after the step of patterning the first material layer through the second openings to form the first film layer, the method further comprises:
patterning the third material layer through the first openings to form a third film layer;
in the step of patterning the third material layer through the first openings, pattern the third material layer through the first openings, by dry etching, to form the third film layer;
after the step of patterning the third material layer through the first openings to form the third film layer, the method further comprises:
patterning the first film layer to make the orthogonal projection of the first film layer on the substrate located within the orthogonal projection of the third film layer on the substrate;
the area of the orthogonal projection of the first film layer on the substrate is smaller than the area of the orthogonal projection of the third film layer on the substrate;
in the step of patterning the first film layer to make the orthogonal projection of the first film layer on the substrate located within the orthogonal projection of the third film layer on the substrate, patterning the first film layer by wet etching.

20. The method according to claim 17, wherein the isolation opening comprises a first isolation opening and a second isolation opening, in the step of forming at least a portion of the film layers of the light-emitting device layer on the substrate, the method further comprises:
forming a first light-emitting material layer, a first electrode material layer, and a first encapsulation material layer in sequence on the substrate;
patterning the first light-emitting material layer, the first electrode material layer, and the first encapsulation material layer to form a light-emitting portion, a first electrode of a first light-emitting unit corresponding to the first isolation opening, and a first encapsulation portion disposed on a side of the first light-emitting unit away from the substrate;
after the step of forming the light-emitting portion, the first electrode of the first light-emitting unit corresponding to the first isolation opening, and the first encapsulation portion disposed on the side of the first light-emitting unit away from the substrate, the method further comprises:
forming a second light-emitting material layer, a second electrode material layer, and a second encapsulation material layer in sequence on the substrate;
patterning the second light-emitting material layer, the second electrode material layer, and the second encapsulation material layer to form a light-emitting portion, a first electrode of a second light-emitting unit corresponding to the second isolation opening, and a second encapsulation portion disposed on a side of the second light-emitting unit away from the substrate;
wherein the extension distance corresponding to the first light-emitting unit is a first distance, the extension distance corresponding to the second light-emitting unit is a second distance, and the first distance is less than the second distance;
the isolation opening further comprises a third isolation opening, after the step of forming the light-emitting portion, the first electrode of the second light-emitting unit corresponding to the second isolation opening, and the second encapsulation portion disposed on the side of the second light-emitting unit away from the substrate, the method further comprises:
forming a third light-emitting material layer, a third electrode material layer, and a third encapsulation material layer on the substrate in sequence;
patterning the third light-emitting material layer, the third electrode material layer, and the third encapsulation material layer to form a light-emitting portion, a first electrode of a third light-emitting unit corresponding to the third isolation opening, and a third encapsulation portion disposed on a side of the third light-emitting unit away from the substrate;
in the step of patterning the first light-emitting material layer, the first electrode material layer, and the first encapsulation material layer, the method further comprises:
dry etching the first encapsulation material layer to form the first encapsulation portion;
wet etching the first electrode material layer to form the first electrode of the first light-emitting unit;
in the step of patterning the second light-emitting material layer, the second electrode material layer, and the second encapsulation material layer, the method further comprises:
dry etching the second encapsulation material layer to form the second encapsulation portion;
wet etching the second electrode material layer to form the first electrode of the second light-emitting unit;
in the step of patterning the third light-emitting material layer, the third electrode material layer, and the third encapsulation material layer, the method further comprises:
dry etching the third encapsulation material layer to form the third encapsulation portion;
wet etching the third electrode material layer to form the first electrode of the third light-emitting unit;
wherein the extension distance corresponding to the third light-emitting unit is a third distance, and the second distance is less than the third distance.
